(19) United States
(12) Patent Application Publication
(10) Pub. No.: US 2025/0112154 A1
(43) Pub. Date: Apr. 3, 2025

(54) Power, Signaling and Thermal Path Co-optimization

(71) Applicant: Apple Inc., Cupertino, CA (US)

(72) Inventors: Sanjay Dabral, Cupertino, CA (US); Antonietta Oliva, Sausalito, CA (US); Sambasivan Narayan, Saratoga, CA (US); Jun Zhai, Cupertino, CA (US); Vidhya Ramachandran, Cupertino, CA (US); Kamal Sikka, Fremont, CA (US)

(21) Appl. No.: 18/643,907

(22) Filed: Apr. 23, 2024

Related U.S. Application Data
(60) Provisional application No. 63/586,645, filed on Sep. 29, 2023.

(51) Int. Cl. H01L 23/528; H01L 23/00; H01L 23/367; H01L 23/427; H01L 23/473; H01L 23/48; H01L 23/522

(52) U.S. Cl. CPC H01L 23/5286; H01L 23/367; H01L 23/427; H01L 23/473; H01L 23/481; H01L 23/5223; H01L 23/5226; H01L 24/05; H01L 24/06; H01L 24/13; H01L 24/16; H01L 24/10; H01L 24/11; H01L 24/17; H01L 24/32; H01L 24/73; H01L 24/81; H01L 2224/0557; H01L 2224/0603; H01L 2224/06051; H01L 2224/06181; H01L 2224/10135; H01L 2224/10165; H01L 2224/11464; H01L 2224/13147; H01L 2224/13155; H01L 2224/13186; H01L 2224/1319; H01L 2224/13193; H01L 2224/16145; H01L 2224/16238; H01L 2224/16258; H01L 2224/17505; H01L 2224/32225; H01L 2224/32245; H01L 2224/73253; H01L 2224/81007; H01L 2224/811; H01L 2224/818; H01L 2924/01006; H01L 2924/04642; H01L 2924/1431

(57) ABSTRACT

Chip structures and electronic modules including a power delivery network (PDN) routing structure and signal routing structure to balance power, signaling, and thermal requirements are described. In an embodiment, the chip includes a device layer, a PDN routing structure on top of the device layer, and a signal routing structure underneath the device layer.

### RELATED APPLICATIONS

This application claims the benefit of priority of U.S. Provisional Application No. 63/586,645, filed Sep. 29, 2023, which is herein incorporated by reference.

### BACKGROUND

### Field

Embodiments described herein relate to semiconductor chip fabrication, and more particularly to power delivery and signal network routing.

### Background Information

Typical high performance logic chips such as processors are designed with both signal and power routing in the back-end-of-the-line (BEOL) stack-up that is formed over a semiconductor substrate and front-end-of-the-line (FEOL) device layer. In a conventional frontside power delivery arrangement the chip contact pads, for example solder bump landing pads for flip chip connection, are formed on the top of the BEOL stack-up in an arrangement known as frontside connection with the chip contact pads. Thus, a frontside connection suggests the chip contact pads are formed on top of the FEOL device layer and semiconductor substrate. In this case the BEOL stack-up is also on the frontside, and is considered as board facing if the chip is flip chip mounted onto a board or other routing substrate. Such a BEOL stack-up may include 10 to 20 metal layers for example with the lower-level and mid-level metal layers designated for signal routing and the top-level metal layers, which are the thickest and widest metal layers with widest pitch, designated for power routing and latency sensitive or long routing. In such a typical configuration, both power delivery and signal routing is on the same side of the chip, and both paths to the device layer proceed through the same metal layers in the BEOL stack-up. However, as the semiconductor process nodes measured by transistor size continue to shrink, this also correlates to finer wiring requirements, which also correlates to increased resistance in the routing through the metal layers. This increased resistance may further contribute to a voltage droop in power delivery. Furthermore, since the metal stack is the same for power delivery and signal interconnect, it needs to be simultaneously sufficiently suitable for both, which may not be optimal for either.

More recently it has been proposed to redistribute power delivery routing to the backside of the chip. In such a backside power delivery arrangement the traditional BEOL stack-up formed on top of the FEOL device layer can be primarily for signal routing, while separate power routing and chip contact pads are formed on a backside (underneath) the FEOL device layer. Since the power network and contact pads are now on the backside of the device layer this arrangement is known as a backside connection. Since the power network and signal routing can be decoupled each one can be better optimized for its function. In such an arrangement the backside power delivery routing can be considered as board facing, for example if the chip is flip chip mounted onto a board or other routing substrate.

### SUMMARY

Chip structures and electronic modules including a power delivery network (PDN) routing structure and signal routing structure to balance power, signaling, and thermal requirements are described. In an embodiment, the chip includes a device layer, a PDN routing structure on top of the device layer, and a signal routing structure underneath the device layer. A variety of materials selection and physical arrangements may be selected to achieve the requisite device performance including thermal conductivity, dielectric constant and thickness of the inter layer dielectric (ILD) layers, thickness and width of the metal routing layers, and vertical connectivity arrangements inclusive of stacked vias, device layer vias and power delivery vias. Moreover, such arrangements may also align the thermal path for heat management of the chip.

### BRIEF DESCRIPTION OF THE DRAWINGS

FIG. 1A is a schematic cross-sectional side view illustration of an electronic module and main thermal path through a chip with backside connection and backside PDN routing structure.

FIG. 1B is a schematic cross-sectional side view illustration of an electronic module and main thermal path through a chip with backside connection and topside PDN routing structure in accordance with an embodiment.

FIG. 2A is a high-level illustration of thermal resistance and capacitance per inter layer dielectric thickness in accordance with embodiments.

FIG. 2B is a high-level illustration of thermal conductivity and relative permittivity for engineering materials in accordance with embodiments.

FIG. 3 is a schematic cross-sectional side view illustration of a chip with backside connection and topside PDN routing structure in accordance with an embodiment.

FIG. 4A is a schematic side view illustration of a signal routing structure metal routing layer spacing in accordance with an embodiment.

FIG. 4B is a schematic side view illustration of a signal routing structure metal routing layer layout in accordance with an embodiment.

FIG. 4C is a schematic top layout view illustration of a signal routing structure metal routing layer layout in accordance with an embodiment.

FIG. 5A is a schematic side view illustration of a PDN routing structure metal routing layer spacing in accordance with an embodiment.

FIG. 5B is a schematic side view illustration of a PDN routing structure metal routing layer layout in accordance with an embodiment.

FIG. 5C is a schematic top layout view illustration of a PDN routing structure metal routing layer layout in accordance with an embodiment.

FIG. 6 is a schematic cross-sectional side view illustration of an electronic module and power delivery path through a chip with backside connection and topside PDN routing structure.

FIG. 7 is a schematic cross-sectional side view illustration of a chip with backside connection and a combination of device layer vias and power delivery vias through a device layer to a topside PDN routing structure in accordance with an embodiment.

FIG. 8 is a schematic cross-sectional side view illustration of a chip including an electrolessly bonded thermal solution in accordance with an embodiment.

FIGS. 9A-9C are schematic cross-sectional side view illustrations of a sequence of electrolessly bonding thermal solution in accordance with an embodiment.

FIG. 10A is a schematic cross-sectional side view illustration of a thermal solution including an active layer in accordance with an embodiment.

FIG. 10B is a schematic cross-sectional side view illustration of a thermal solution including passive devices in accordance with an embodiment.

FIG. 10C is a schematic cross-sectional side view illustration of a thermal solution including micro channels in accordance with an embodiment.

FIG. 10D is a schematic cross-sectional side view illustration of a thermal solution including an active layer and optical path in accordance with an embodiment.

### DETAILED DESCRIPTION

Embodiments describe chip structures and electronic modules including a power delivery network (PDN) routing structure and signal routing structure to balance power, signaling, and thermal requirements. In an embodiment a chip structure includes a device layer, a PDN routing structure on top of the device layer, and a signal routing structure underneath the device layer. In accordance with embodiments the metal routing layers of the PDN routing structure may be thicker and wider than the metal routing layers of the signal routing structure.

In one aspect, embodiments describe chip structure and electronic modules in which the routing structures for signal routing and a PDN are decoupled from one another in a particular arrangement to balance signaling and power requirements, while also balancing thermal requirements in order to not negate the intended gains associated with decoupling the signal routing and PDN routing. For example, it has been observed that with previous proposals for a backside power delivery arrangement with backside PDN routing and topside signal routing that the thermal path of the device may be sub-optimal in that the thermal path is impeded by the thermal resistance of the stack-ups on either side of the device layer. In accordance with embodiments both signal and power delivery can be co-optimized, while also being aligned with the main thermal path of the chip. This can be achieved by decoupling the signal routing structure and PDN routing structure, and locating the PDN routing structure on the topside of the device layer and closer to a thermal solution (also referred to as a thermal packaging solution). The signal routing structure can be designed with line width, space, and height supporting the device layer density, energy requirements, and RC. The PDN routing structure can then be designed with inter layer dielectric (ILD) layers with higher thermal conductivity (kₜₕₑᵣₘₐₗ) to facilitate heat flow along the intended thermal path (i.e. to the thermal solution). Furthermore, metal routing layers in the PDN routing structure can be thicker, wider for low resistance and finely spaced to increase packing density, which can assist with thermal conductivity along the thermal path, and also allow the integration of devices with electromagnetic properties. For example, the PDN routing structure can include integrated capacitors. ILD layers with higher thermal conductivity may also have higher dielectric constants, which can also support higher capacitance.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “underneath”, “to”, “between”, and “on” as used herein may refer to a relative position of one layer with respect to other layers. One layer “over”, “underneath”, or “on” another layer or bonded “to” or in “contact” with another layer may be directly in contact with the other layer or may have one or more intervening layers. One layer “between” layers may be directly in contact with the layers or may have one or more intervening layers.

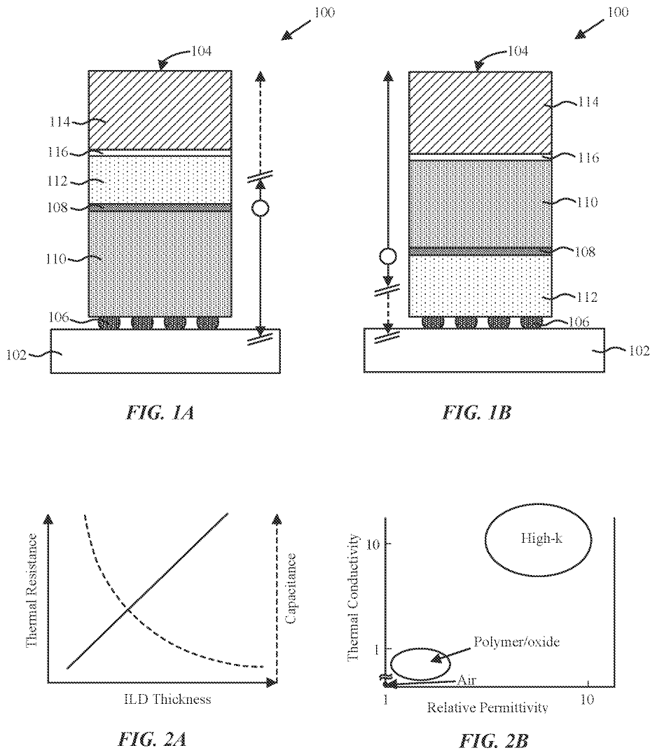

In accordance with embodiments, the PDN routing structure can be decoupled from the signal routing structure to facilitate electrical performance gains. In accordance with embodiments, the thermal path for heat management can also be controlled. Referring now to FIGS. 1A-1B, FIG. 1A is a schematic cross-sectional side view illustration of an electronic module and main thermal path through chip with backside connection and backside PDN routing structure; FIG. 1B is a schematic cross-sectional side view illustration of an electronic module and main thermal path through a chip with backside connection and topside PDN routing structure in accordance with an embodiment. As shown in each of FIGS. 1A-1B, the electronic modules 100 each include a routing substrate 102, such as an interposer or printed circuit board (PCB), and a chip 104 mounted on the routing substrate 102. For example, the chip 104 can be flip chip mounted onto the routing substrate 102 with a plurality of solder bumps 106. The chips 104 can each include a device layer 108, a PDN routing structure 110 and signal routing structure 112. A thermal solution 114 (such as a thermal lid, heat sink, heat spreader, etc.) can additionally be included as part of the chip 104 or as a separate component. The thermal solution 114 can be a single layer or material, or may be a combination of multiple layers, materials and structures. For example, a thermal solution 114 can be formed of a variety of thermally conductive materials, including metal, aluminum nitride, silicon, diamond, silicon carbide, etc. The thermal solution 114 may also provide mechanical support, and thus function as a thermal-mechanical solution. In an embodiment, the thermal solution is formed of a silicon substrate, which has sufficient thermal conductivity to function as a heat sink and a coefficient of thermal expansion (CTE) compatible with chip materials. The thermal solution can be bonded to the underlying routing structure with a bonding layer 116, which can be a thin oxide, metal, solder, etc. In an embodiment the thermal solution is bonded to the underlying structure with oxide-oxide bonding of bonding layers 116. In another embodiment, thermal solution is bonded to the underlying structure with metal bonding such as with metal diffusion bonding (e.g., aluminum-aluminum metal layers) or transient liquid phase (TLP) bonding where one or more intermetallic compounds are formed by interdiffusion of bonding layers 116. Other bonding techniques such as hybrid bonding (including metal-metal and oxide-oxide bonds), bonding with anisotropic conductor film (ACF), such as a film including a compressive core (e.g., metal or polymer particles/balls) with solder skin/shells, silicon bonding techniques (e.g., cyclopentasilane, or ink including silicon nanocrystals such as a silicon concrete including silicon nanocrystals dispersed in a silicon matrix), as well as electroless bumping, electroless (liquid) atomic layer deposition (ALD), and gas phase ALD bonding may be used.

In the particular configuration illustrated in FIG. 1A the signal routing structure 112 is on top of the device layer 108, while the PDN routing structure is underneath the device layer 108. In the particular embodiment illustrated in FIG. 1B the PDN routing structure is on top of the device layer 108, while the signal routing structure 112 is underneath the device layer 108. As shown by the arrows, heat is generated in the device layer. In the particular configuration of FIG. 1A the main thermal path is mis-aligned due to the signal routing structure 112 and routing substrate 102 both being characterized by low thermal conductivity. As such, generated heat may not be adequately dissipated. In the embodiment illustrated in FIG. 1B the main thermal path is aligned, with the PDN routing structure characterized by a comparatively higher thermal conductivity, which facilitates heat transfer to the thermal solution 114 and chip efficiency. The differences in thermal paths can be attributed to a combination of process conditions including forming the ILD layers in the PDN routing structure 110 with a higher thermal conductivity material, and increased metal density and size of the metal routing layers (with less dielectric material). By way of example, the PDN routing structure may have a thermal resistance of less than a thermal resistance of the signal routing structure 112. Even a difference of 0.1 C*mm²/W can have a measurable impact with heat transfer.

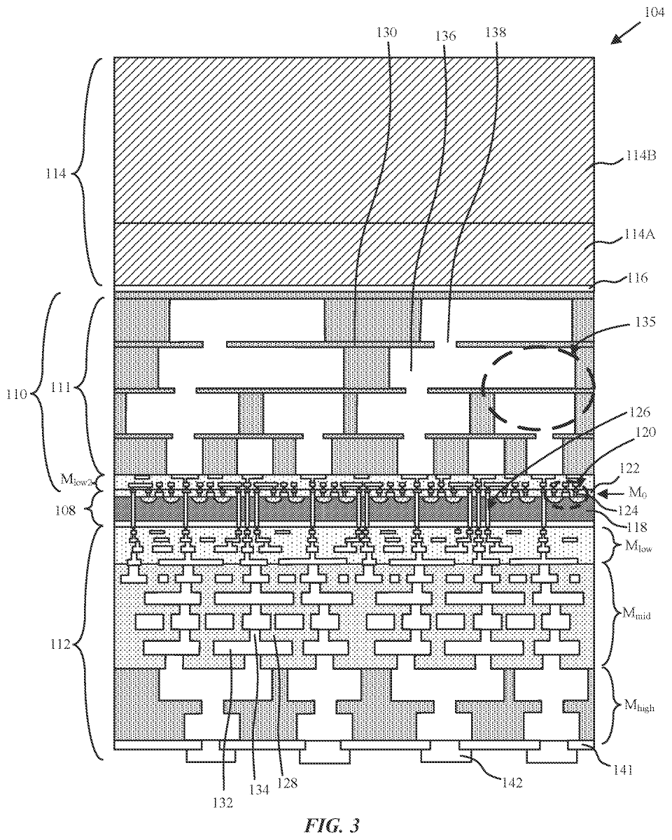

Referring now to FIGS. 2A-2B, FIG. 2A is a high-level illustration of thermal resistance and capacitance per inter layer dielectric (ILD) thickness in accordance with embodiments; FIG. 2B is a high-level illustration of thermal conductivity and relative permittivity (e.g., dielectric constant, εᵣ) for integrated circuit (IC) engineering materials in accordance with embodiments. As will be described in further detail with regard to FIG. 3, the signal routing structure 112 and PDN routing structure 110 can include a plurality of metal routing layers separated by ILD layers. Signal routing structure 112 requirements may call for low capacitance between wiring layers, which can be achieved with low dielectric constant (low-k) ILD materials, and thicker ILD layers. As shown in FIG. 1A however, inclusion of low-k ILD materials, and thicker ILD layers in the signal routing structure 112 can impede the thermal path to the thermal solution 114 due to the corresponding lower thermal conductivity and higher thermal resistance of the ILD layers, and overall stack-up of the signal routing structure 112. In the embodiment illustrated in FIG. 1B however, the PDN routing structure 110 can instead be located over the device layer 108, where the PDN routing structure 110 stack-up can include ILD layers with smaller thickness between metal routing layers and formed of materials with high dielectric constants (high-k). As shown in FIG. 1B, the thermal path to the thermal solution 114 is facilitated by selection of higher electrical dielectric constant and higher thermal conductivity ILD materials, and smaller thicknesses in the PDN routing structure 110.

FIG. 3 is a schematic cross-sectional side view illustration of a chip 104 with backside connection and topside PDN routing structure in accordance with an embodiment. The device layer 108 in accordance with embodiments may be formed in a semiconductor layer 118, including a semiconductor wafer such as a silicon wafer or III-V wafer, etc. Additionally, the device layer 108 may be formed in a top epitaxial layer of a silicon-on-insulator (SOI) substrate, or bulk silicon substrate, etc. A plurality of devices 120 are then formed in the semiconductor layer 118. For example, doped well regions and source/drain regions can be formed in the semiconductor layer 118 using suitable diffusion techniques. A gate is then formed over the channel region between the source/drain regions using suitable techniques, such as polysilicon deposition. Silicide contacts may then be made on the gate and source/drain regions as is known. The gate can then be insulated in a dielectric layer 122, followed by the formation of plug contacts 124 to the gate and source/drain regions. For, example, the plug contacts can be formed by etching and deposition of a suitable conductive material, such as tungsten, though embodiments are not so limited. Some amount of metal routing may also be included. Together, these conductive plug contacts and optional routing form what may be known as the metal zero (M₀) layer, which may be understood as representing the end of the FEOL process. It is to be appreciated that while a plurality of planar transistors are illustrated that this is exemplary, and embodiments are not so limited. For example, the transistors can be nonplanar transistors including various double gate transistors, trigate transistors, gate all around transistors, etc. Furthermore, the thickness of semiconductor layer 118 can be nonexistent with some designs where, the device layer 108 includes primarily just the transistors and dielectric.

In the particular embodiment illustrated a plurality of device layer vias 126 (e.g., nano TSVs, micro TSVs) may be formed through the semiconductor layer 118 and connect either directly to the devices 120, to the metal zero (M₀) layer routing, or additionally extend through the dielectric layer 122 to connect with routing layers to be subsequently formed. The device layer vias 126 may for example be nano vias with a width of less than 200 nm, such as approximately 100 nm, and may have a pitch of tens to hundreds of nm in order to contact the devices. The semiconductor layer 118, and hence the device layer vias 126, may have a thickness and height on the order of hundreds of nm, such as 200-500 nm. Micro vias may have larger widths and heights. It is to be appreciated that the bulk semiconductor substrate on which the device layer 108 is formed may still be present during the formation of the device layer 108, and that the device layer vias 126 need not extend further than the thickness of the device layer 108.

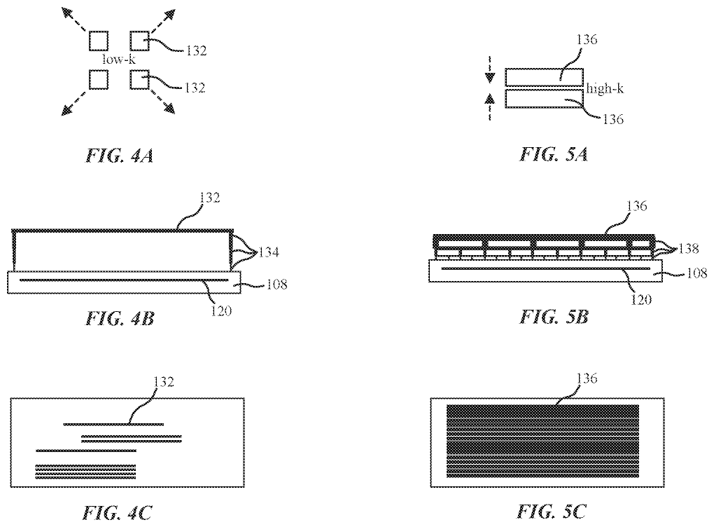

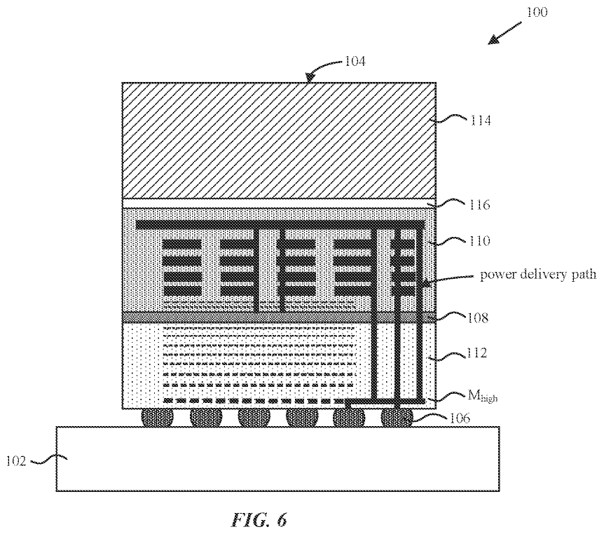

Referring now briefly to FIGS. 4A-4C and FIGS. 5A-5C, a schematic side view illustration of signal routing structure metal routing layer 132 showing spacing (FIG. 4A), and schematic side view (FIG. 4B) and top layout view (FIG. 4C) illustrations of signal routing structure metal routing layers 132 layouts are provided for comparison with a schematic side view illustration of PDN routing structure metal routing layer 136 spacing (FIG. 5A), and schematic side view (FIG. 5B) and top layout view (FIG. 5C) illustrations of PDN routing structure metal routing layer 136 layouts in accordance with embodiments. For example, as shown in FIGS. 4A and 5A, wiring within a signal routing structure 112 may include sparse wiring and vias separated with low dielectric constant (low-k) ILD layers that are relatively non-thermally conductive, while a PDN routing structure 110 may include wide metal routing planes that are separated with a high dielectric constant (high-k) ILD layers, and may have a higher via density. In such a configuration the PDN routing structure 110 may have a higher thermal conductivity than the signal routing structure 112. FIGS. 4B and 5B illustrate a sparser/longer signal routing structure 112 network wiring compared to the PDN routing structure 110 wiring network, which can be denser (more closely spaced metal routing layers, and via density, as well as thickness of the metal layers). FIG. 4C illustrates a sparser layout of signal wires compared to metal planes of the PDN routing structure shown in FIG. 5C. Each of the comparisons may be referenced in the following discussion of FIG. 3.

Still referring to FIG. 3, the PDN routing structure 110 can then be formed over the device layer 108. The PDN routing structure 110 may be formed over the device layer 108 using traditional BEOL build-up structure techniques including dual damascene processing for complementary metal oxide transistor (CMOS) chips fabrication. The PDN routing structure 110 may also be non-CMOS technologies, such as ultra-fine ceramic technologies formed using high temperatures not feasible with CMOS technology, and then bonded using wafer on wafer (WoW) or chip on wafer (CoW) assembly, which may include hybrid bonding, electroless bumping, etc. The PDN routing structure 110 can include a combination of growth and bonding techniques.

The PDN routing structure 110 may include a main power network structure 111 and optionally one or more second lower metal routing layers (M_{low2}) with fine wiring in order to provide requisite device wiring requirements. It may not be feasible for coarse wiring of the main power network structure 111 to make direct contact with the transistors, and thus the second lower metal routing layers may be included in the PDN routing structure 110. Inclusion of the second lower metal routing layers within the PDN routing structure 110 may also improve signal routing compared to previous proposals for a backside power delivery arrangement with backside PDN routing and topside signal routing, where it has been observed that random logic is limited by the number of metal layers in the backside PDN routing. In accordance with embodiments the backside signal routing structure 112 and second lower metal layers (M_{low2}) within the topside PDN routing structure 110 can provide increased wiring capabilities for logic.

As described above the PDN routing structure 110 can be formed with a combination of deposition and bonding techniques. For example, the second lower metal routing layers (M_{low2}) can be formed using traditional BEOL and CMOS processing techniques, while the main power network structure 111 can also be similarly formed, can also be formed using different technologies and bonded to the second lower metal routing layers (M_{low2}), for example through hybrid bonding or electroless bumping.

A thermal solution 114 may then be formed over the PDN routing structure 110. Alternatively, the thermal solution 114 may be formed with the PDN routing structure 110 prior to bonding the PDN routing structure to the device layer 108. For example, a bonding layer 116 such as a thin oxide layer or other combination of dielectric layers can be used for oxide-oxide or dielectric-dielectric bonding. Metal layers may also be used for metal-metal bonding to increase thermal conductivity. Other bonding techniques such as hybrid bonding (including metal-metal and oxide-oxide bonds), bonding with anisotropic conductor film (ACF), such as a film including a compressive core (e.g., metal or polymer particles/balls) with solder skin/shells, silicon bonding techniques (e.g., cyclopentasilane, or ink including silicon nanocrystals), as well as electroless bumping may be used. The thermal solution 114 may also function as a handle wafer during subsequent processing. At this point the bulk substrate supporting the device layer 108 may be thinned or removed using any suitable technique such as grinding or a lift-off technique and polishing. The signal routing structure 112 may then be formed on the backside of the device layer 108. This may be followed by formation of passivation layer 141, such as a silicon nitride, and chip contact terminal 142 formation, such as metal stud contacts of landing pads for solder bump drop.

By way of example, the thermal solution 114 can be formed of multiple layers and materials. In the exemplary embodiment illustrated the thermal solution can include a lower portion 114B compatible with supporting a thin device layer 108, while the upper portion 114B can be suitable for traditional system thermal solutions, such as thermal lid, heat sink, heat spreader, etc. The lower and upper portions 114A, 114B can be the same continuous material such as silicon, diamond, etc. In other configurations the lower portion 114A may be silicon, diamond, etc. followed by a second material for upper portion 114B such as metal.

The signal routing structure 112 may be formed using more traditional BEOL build-up structure CMOS processing techniques, materials and technology nodes. The signal routing structure 112 may include a plurality of metal routing layers 132 separated by ILD layers 128, and connected with vias 134 extending through the ILD layers 128. Wiring layer thickness may be different depending upon wiring level. For example lower metal layers (M_{low}) may have the finest wiring sizes, with upper metal layers (M_{high}) having coarser wiring sizes and larger thicknesses and line widths, with mid-level metal layers (M_{mid}) being somewhere in between. Optionally some upper metal layers (M_{high}) may be used for the power delivery network. The total number of metal routing layers 132 may vary depending upon technology node and type of chip, and may commonly vary between 10 and 20 total metal routing layers 132. The ILD layers 128 separating the respective metal routing layers 132 within M_{low}, M_{mid}, M_{high} may also be different dielectric materials with different dielectric constants, with the ILD layers 128 surrounding and separating the lower metal layers (M_{low}) having the lowest dielectric constant. The ILD layers 130 surrounding and separating the second lower metal layers (M_{low2}) may be formed of similar materials, with similar dielectric constants, as those ILD layers 128 surrounding and separating the lower metal layers (M_{low}). Thus, the ILD layers 130 surrounding and separating the metal layers within the main power network structure 111 may be formed of different materials and have higher dielectric constants than at least those IDL layers surrounding and separating metal routing layers 132 within M_{mid}, M_{high} of signal routing structure 112.

The signal routing structure 112 and PDN routing structure 110 may be de-coupled in accordance with embodiments to address competing interests. For example, the signal routing structure 112 may require larger ILD layer 128 thickness between metal routing layers 132 in order to keep capacitance low. Likewise, line spacing within a metal routing layer may be further apart for similar reasons. Additionally, low-k dielectric materials may be used for the ILD layers 128. Suitable low-k dielectric materials include fluorosilicate glass (FSG), hydrogen silsesquioxane (HSQ), carbon doped oxide (CDO), polymer, methylsilsesquioxane (MSQ), xerogels, etc. Many low-k dielectric materials may also be porous. While it is not a direct relationship, low dielectric constant materials are generally associated with a low thermal conductivity, which can be beneficial for signal integrity. The ILD layers 130 of the PDN routing structure 110 however may be formed of materials with higher thermal conductivity. While the relationship with dielectric constant is not a direct correlation, high dielectric constant (high-k) materials may be selected that have a dielectric constant greater than 4, such as 5-10 or higher, and are fabrication process friendly. Exemplary high-k materials include oxides, nitrides, oxynitrides, silicon, silicon nitride (Si₃N₄), and more exotic technical ceramics such as alumina (Al₂O₃), boron carbide (B₄C), tungsten carbide (WC), aluminum nitride (AlN), silicon carbide (SiC), etc. The metal routing layers 136 PDN routing structure 110, and in particular those within the main power network structure 111, may be thicker and wider than the metal routing layers of the signal routing structure 112, and in particular those above M_{low}. Likewise vias 138 may be wider than vias 134, and there may be a higher via density within the PDN routing structure 110 compared to the signal routing structure 112. For example, the PDN routing structure 110 can include a via density greater than 10% by volume within a via/dielectric layer (as well as an entirety of the PDN routing structure 110), while the signal routing structure 112 via density is less than 5% by volume within a via/dielectric layer (as well as an entirety of the signal routing structure 112).

Still referring to FIG. 3, the ILD layers 128 of the signal routing structure 112 may have a thickness of 1 μm for resistance, capacitance and density requirements. The ILD layers 130 of the PDN routing structure 110, and in particular those of the main power network structure 111, however may be much thinner such as at least half the thickness of the ILD layers 128 (exclusive of any common M_{low} layers). For example, ILD layers 130 may be 0.05-0.5 μm thick. For illustrational purposes, upper metal layers M_{high} in the signal routing structure 112 may be separated by a silicon oxide ILD layer 128 of 0.5-1 μm thickness, and dielectric constant of 3.9, while metallization layers of the PDN routing structure 110 may be separated by a high-k ILD layer 130 of 0.1 μm thickness and dielectric constant of 9. Such a change in parameters may lead to a 22.5 times larger capacitance per area (9×1)/(4×0.1)=22.5 C/mm² ratio. Such an increase may further facilitate the inclusion of integrated capacitors 135 in the PDN routing structure 110. For example, such capacitors may be metal-insulator-metal (MIM) capacitors formed between planes in the metallization layers, possibly with a high dielectric constant (high-k) dielectric ILD material (e.g., with dielectric contact above 4).

FIG. 6 is a schematic cross-sectional side view illustration of an electronic module and power delivery path through a chip with backside connection and topside PDN routing structure. As shown, the power delivery network may receive high power (Vdd) and low power (Vss) signals from the routing substrate 102, for example through solder bumps 106. These signals may optionally be globally routed in one or more upper metal layers (M_{high}) of the signal routing structure 112, and then vertically transmitted through the signal routing structure 112, through the device layer 108 and into the PDN routing structure 110, where the signals may be further routed globally, and distributed to the devices in the device layer 108. It has been observed that a potential electrical weakness can be with sharing the metal routing layers and dielectric layers that have been designed for signal delivery and transmission within the signal routing structure 112. For example, finer line thicknesses and via widths may lead to higher electrical resistance.

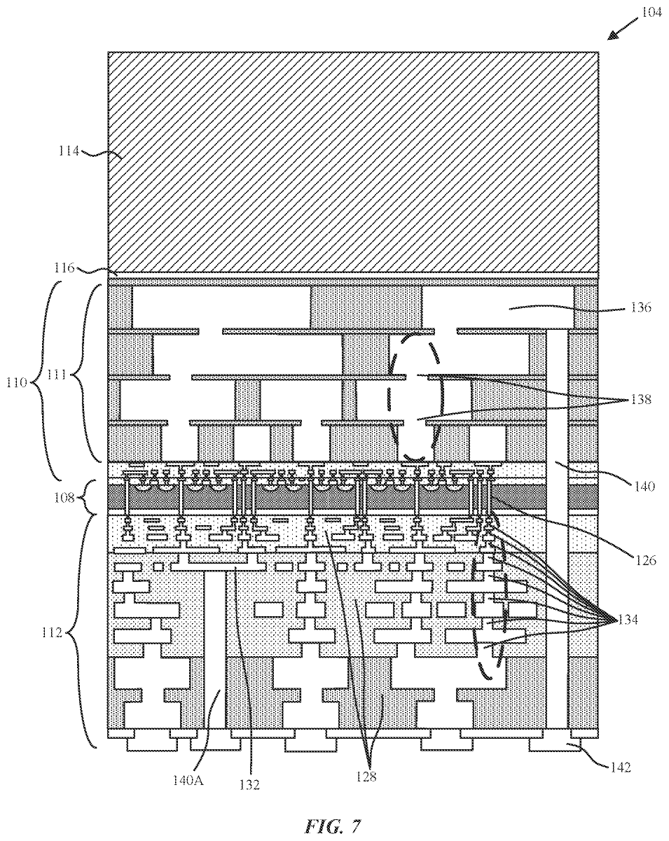

FIG. 7 is a schematic cross-sectional side view illustration of a chip with backside connection and a combination of device layer vias 126 and power delivery vias through a device layer to a topside PDN routing structure in accordance with an embodiment. In particular, the embodiment illustrated in FIG. 7 shows several structural arrangements that can be used, alone or in any combination, to mitigate electrical resistance. For example, stacked vias may be used in order to shorten the electrical power delivery path. As shown vias 134 within the signal routing structure 112 can be stacked so that the directly adjacent vias at least partially overlap one another. The stacked vias 134 may proceed through a majority, or all of the signal routing structure 112. Similarly arranged stacked vias 138 may also be utilized in the PDN routing structure 110. In the particular embodiment illustrated the stacked vias 134 are connected to the device layer vias 126 extending through the device layer 108. Alternatively, power delivery vias 140 can be included. Custom power delivery vias 140 can be wider than the device layer vias 126, such as order of microns or tens of microns. Power delivery vias may also extend through a thicker device layer 108, and may optionally extend further into either the signal routing structure 112 and/or PDN routing structure 110. Thus, while the power delivery vias 140 illustrated extends through both the signal routing structure 112 and/or PDN routing structure 110, this is meant to show an extreme example, and power delivery vias 140 can extend though any thickness, ranging from the device layer to any thickness, or partial thickness of the surrounding routing layers. In an alternative variation also shown, power delivery vias can extend through or partially through one of the routing layers. For example, also shown is power delivery via 140A that extends partially through the signal routing structure 112, and then branches out with metal routing layers 132 for connection to the device layer vias 126. In this configuration, much of the metal routing layers of the signal routing structure 112 can be bypassed with power delivery vias 140A used for power delivery. Furthermore, the power delivery vias 140, 140A can have customized heights, or delivery paths, with less interfaces. For example, common diffusion barriers, and metal-metal layers between various vias and metal routing layers can be avoided, instead forming a continuous metal (e.g., copper) power delivery via through multiple metal and dielectric layers without having to pass through multiple interfaces, which may still be present in a stacked via arrangement, for example.

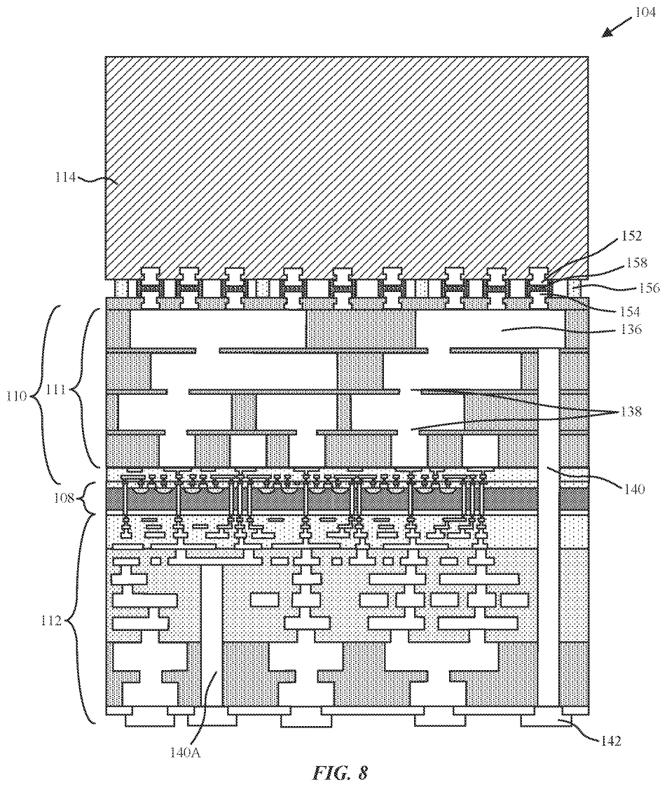

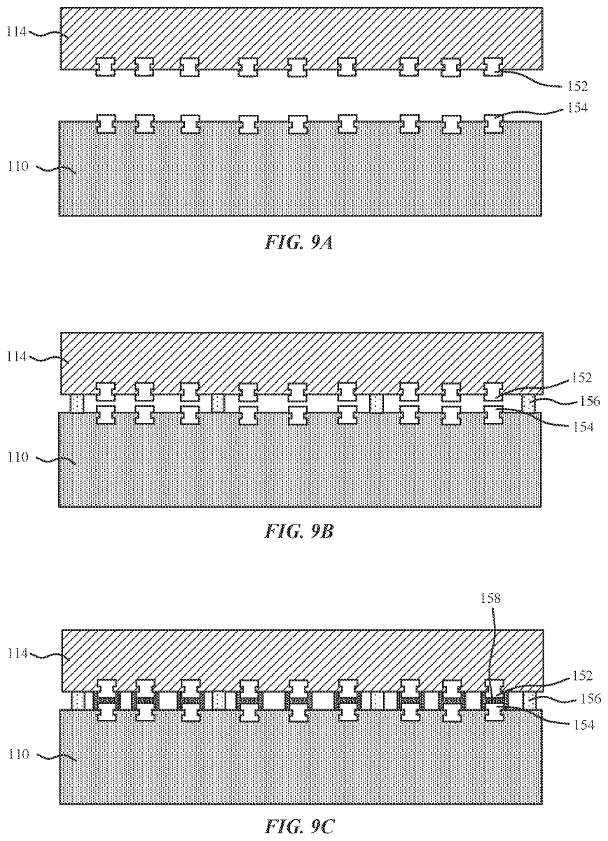

FIG. 8 is a schematic cross-sectional side view illustration of a chip including an electrolessly bonded thermal solution 114 in accordance with an embodiment. FIGS. 9A-9C are schematic cross-sectional side view illustrations of a sequence of electrolessly bonding thermal solution in accordance with an embodiment. As shown, the thermal solution 114 can include a plurality of bonding pads 152 aligned with bonding pads 154 of the PDN routing structure 110. For example, each of the bonding pads 152 can be copper pads or protruding studs. As shown in FIG. 9A-9B, the thermal solution 114 and PDN routing structure 110 can be aligned, and the secured over one another using either a pressure plate and/or optional spacers 156, which can be used to adhere the structures to one another and/or control spacing between the aligned bonding pads 152, 154. The optional spacers can be formed of an adhesive material (e.g., polymer) for example, to aid in aligning the thermal solution 114 and PDN routing structure 110 and to hold the structures in place during electroless deposition. The treated and aligned structures can then be placed into an electroless bath for growth of the metallic joints 158 between the aligned bonding pads 52, 154 as shown in FIG. 9C. For example, the metallic joints 158 may be formed copper, nickel, copper alloys, nickel alloys, etc. In this manner metallic joints 158 with high melting temperatures (e.g., of copper and nickel) can be formed without subjecting the bonded structure to high temperature. The metallic joints 158 can also be loaded with materials, such as diamond or SiC, to improve thermal performance. For example, a metallic joint 158 may include nickel loaded with additional material, such as diamond or SiC. This may increase the thermal conductivity closer to copper, and bring the coefficient of thermal expansion closer to silicon, allowing higher area fraction utilization.

The thermal solutions 114 in accordance with embodiments may provide a variety of functions. For example, the thermal solutions can be formed of various enhanced thermal materials such as SiC, diamond, AlN, composites, etc. in order to improve thermal characteristics of the chip while keeping warpage and manufacturability limitations. Further, such lids may add some functions such as capacitors, optical elements, micro channels, etc.

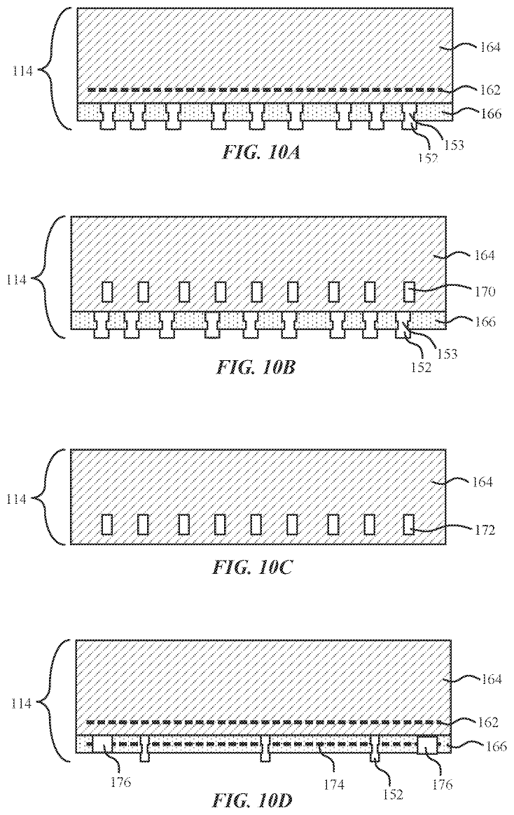

FIG. 10A is a schematic cross-sectional side view illustration of a thermal solution including an active layer 162 in accordance with an embodiment. In such an embodiment, the active layer 162 may be formed within a bulk layer 164, such as a semiconductor material (e.g., silicon), and may off-load certain logic from the underlying device layer of the chip. The active layer 162 may include a plurality of logic devices, e.g., transistors, etc. In order to make electrical connection to the active layer 162, various electrical and thermal interconnects 153 (e.g., vias, and any other routing) can be included, which may optionally extend through one or more dielectric layers 166.

FIG. 10B is a schematic cross-sectional side view illustration of a thermal solution 114 including passive devices 170 in accordance with an embodiment. For example, the passive devices 170 can be deep trench capacitors formed in the bulk layer 164 and electrically connected with the PDN routing structure through interconnects 153.

FIG. 10C is a schematic cross-sectional side view illustration of a thermal solution 114 including micro channels 172 in accordance with an embodiment. For example, the micro channels 172 may be filled with a flowing liquid (or phase change fluids) to further assist with cooling.

FIG. 10D is a schematic cross-sectional side view illustration of a thermal solution 114 including an optional active layer 162 and optional optical path 174 in accordance with an embodiment. The active layer 162, when present, may support optical or other functions. The optical path 174 may for example include a waveguide or optical fiber. The optical path may be further connected to various optical components 176 including modulators, couplers, optical detectors (e.g., diodes), optical emitters (e.g., light emitting diode, laser), etc. Interconnects 153 may also be present for electrical and/or thermal. In some embodiments the optical components are optical-to-electrical (O/E) and electrical-to-optical (E/O) converters. For example, the thermal solution 114 can receive/transfer optical communication from/to the PDN routing structure 110. In this manner the thermal solution 114 and PDN routing structure 110 (or underlying structure) can have complementary receiver/transceivers. Alternatively, the optical path can be wholly contained within the thermal solution 114.

In an embodiment, an electronic module includes a routing substrate 102 and a chip 104 mounted on the routing substrate 102. In accordance with embodiments the chip includes a device layer 108, a PDN routing structure 110 on top of the device layer 108, and a signal routing structure 112 underneath the device layer 108. The PDN routing structure 110 may be characterized by a higher thermal conductivity than the signal routing structure 112. The signal routing structure 112 may include a first plurality of metal routing layers 132, and the PDN routing structure 110 includes a second plurality of metal routing layers 136. For example, an average thickness of the second plurality of metal routing layers 136 may be greater than an average thickness of the first plurality of metal routing layers 132. This can be particularly true if the lower metal layers M_{low} and M_{low2} are not considered. The signal routing structure 112 can additionally include a plurality of chip contact terminals 142 for bonding to the routing substrate 102, for example with a plurality of solder bumps 106.

In accordance with embodiments a thermal solution 114 (e.g., thermal lid, heat sink, heat spreader, etc.) is bonded to a top side of the PDN routing structure 110 in order to draw heat away from the routing structures and device layer. The signal routing structure 112 may include a first plurality of ILD layers 128, while the PDN routing structure 110 includes a second plurality of ILD layers 130 characterized by a higher dielectric constant than the first plurality of ILD layers 128. For example, the second plurality of ILD layers may have a dielectric constant greater than 4, such as 5-9 or greater.

In an embodiment, a plurality of power delivery vias 140, 140A extend through more than one of the first plurality of metal routing layers 132 and the first plurality of ILD layers 128 in the signal routing structure 112.

The PDN routing structure 110 in accordance with embodiments can include less metal routing layers than the signal routing structure 112. The PDN routing structure 110 can have a higher metal content than the signal routing structure 112, and the PDN routing structure 110 can also be thicker than the signal routing structure 112. In accordance with embodiments, the PDN routing structure 110 can include a larger via density than the signal routing structure. For example, the PDN routing structure 110 can include a via density greater than 10% by volume, while the signal routing structure 112 via density is less than 5% by volume. The vias 138 within the PDN routing structure may also be shorter than the vias 134 within the signal routing structure 112. This may be particularly true for the mid-level vias (M_{mid}) and upper level vias (M_{high}) in the signal routing structure 112. As another characterization, the average ratio of via 138 height to metal routing layer 136 thickness within the PDN routing structure 110 may be shorter than the average ratio of via 134 height to metal routing layer 132 thickness within the signal routing structure 112. The thinner ILD layers 130 may facilitate the integration of capacitors 135 within the PDN routing structure 110, particularly when located between power planes formed in the metal routing layers 136.

Vertical connection from the routing substrate 102 to the PDN routing structure 110 may be facilitated by a combination of features including stacked vias 134 within the signal routing structure 112 and/or stacked vias 138 within the PDN routing structure 110, device layer vias 126 extending through the device layer 108, and/or power delivery vias 140 extending through the device layer 108 and optionally though a portion or all of either of the signal routing structure 112 and PDN routing structure 110. Depending on the type of active device (e.g., planar transistor, fin field-effect transistor (FinFET), gate all around transistor, etc.) in device layer 108 silicon thickness varies, therefore device layer via 126 may be TSV through some silicon or largely a via transitioning through a thin silicon layer.

The thermal solution 114 in accordance with embodiments can be bonded to the top side of the PDN routing structure in a variety of manners, and the thermal solution may perform a variety of functions. In an embodiment, the thermal solution is bonded to the top side of the PDN routing structure with a uniform metallic layer (for example, with metal-metal diffusion bonding, TLP bonding, etc.). In an embodiment, the thermal solution comprises a first plurality of bonding pads, the PDN routing structure comprises a second plurality of bonding pads, and the first plurality of bonding pads is bonded to the second plurality of bonding pads with a plurality of metallic joints. For example, this may be accomplished with electroless bonding. In an embodiment, the plurality of metallic joints has a melting temperature greater than melting temperatures of the first plurality of bonding pads and the second plurality of bonding pads.

The thermal solution may include logic devices and/or passive devices such as deep trench capacitors electrically connected with the PDN routing structure. In some embodiments the thermal solution can include an optical path, inclusive of various components including any of a waveguide, optical wire, converters, modulators, etc. In utilizing the various aspects of the embodiments, it would become apparent to one skilled in the art that combinations or variations of the above embodiments are possible for forming a chip with backside connection and a topside PDN routing structure. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A chip structure comprising:
a device layer;
a power delivery network (PDN) routing structure on top of the device layer; and
a signal routing structure underneath the device layer;
wherein the signal routing structure includes a first plurality of metal routing layers, and the PDN routing structure includes a second plurality of metal routing layers, and the PDN routing structure is characterized by a higher thermal conductivity than the signal routing structure.

2. The chip structure of claim 1, wherein the signal routing structure further comprises a plurality of chip contact terminals.

3. The chip structure of claim 2, wherein the signal routing structure includes a first plurality of inter layer dielectric (ILD) layers, and the PDN routing structure includes a second plurality of ILD layers characterized by a higher dielectric constant than the first plurality of ILD layers.

4. The chip structure of claim 3, further comprising a plurality of power delivery vias extending through more than one of the first plurality of metal routing layers and through more than one of the first plurality of ILD layers in the signal routing structure.

5. The chip structure of claim 3, wherein the second plurality of ILD layers have a dielectric constant greater than 4.

6. The chip structure of claim 2, wherein the PDN routing structure comprises less metal routing layers than the signal routing structure.

7. The chip structure of claim 2, wherein the PDN routing structure includes a higher metal content than the signal routing structure.

8. The chip structure of claim 2, wherein the PDN routing structure comprises a larger via density than the signal routing structure.

9. The chip structure of claim 8, wherein the PDN routing structure via density is greater than 10% by volume, and the signal routing structure via density is less than 5% by volume.

10. The chip structure of claim 2, wherein the PDN routing structure comprises a smaller average ratio of via height: metal routing layer thickness than the signal routing structure.

11. The chip structure of claim 10, wherein the PDN routing structure comprises power planes.

12. The chip structure of claim 2, further comprising a plurality of device layer vias extending through the device layer.

13. The chip structure of claim 2, wherein the PDN routing structure comprises integrated metal-insulator-metal (MIM) capacitors.

14. The chip structure of claim 2, wherein an average thickness of the second plurality of metal routing layers is greater than an average thickness of the first plurality of metal layers.

15. The chip structure of claim 2, further comprising a thermal solution bonded to a top side of the PDN routing structure.

16. The chip structure of claim 15, wherein the thermal solution is bonded to the top side of the PDN routing structure with a uniform metallic layer.

17. The chip structure of claim 15, wherein the thermal solution comprises a first plurality of bonding pads, the PDN routing structure comprises a second plurality of bonding pads, and the first plurality of bonding pads is bonded to the second plurality of bonding pads with a plurality of metallic joints.

18. The chip structure of claim 17, wherein the plurality of metallic joints has a melting temperature greater than melting temperatures of the first plurality of bonding pads and the second plurality of bonding pads.

19. The chip structure of claim 15, wherein the thermal solution comprises logic devices.

20. The chip structure of claim 15, wherein the thermal solution comprises a plurality of deep trench capacitors electrically connected with the PDN routing structure.

21. The chip structure of claim 15, wherein the thermal solution includes an optical path.

22. An electronic module comprising:
a routing substrate; and
a chip mounted on the routing substrate the chip comprising:
a device layer;
a power delivery network (PDN) routing structure on top of the device layer; and
a signal routing structure underneath the device layer;
wherein the signal routing structure includes a first plurality of metal routing layers, and the PDN routing structure includes a second plurality of metal routing layers, and the PDN routing structure is characterized by a higher thermal conductivity than the signal routing structure.

23. The electronic module of claim 22, wherein the signal routing structure further comprises a plurality of chip contact terminals, wherein the chip contact terminals are bonded to the routing substrate with a plurality of solder bumps.

24. The electronic module of claim 22, wherein an average thickness of the second plurality of metal routing layers is greater than an average thickness of the first plurality of metal layers.

25. The electronic module of claim 22, further comprising a plurality of power delivery vias extending through more than one of the first plurality of metal routing layers and through more than one of a first plurality of inter layer dielectric (ILD) layers in the signal routing structure.
